(19) United States
(12) Patent Application Publication
(10) Pub. No.: US 2015/0064484 A1
(43) Pub. Date: Mar. 5, 2015

(54) COLORED POLYIMIDE FILM AND METAL LAMINATE STRUCTURE INCLUDING THE POLYIMIDE FILM

(71) Applicant: TAIMIDE TECHNOLOGY INCORPORATION, Hsinchu County (TW)

(72) Inventors: Wen-Hsuan Chung, Hsinchu Hsien (TW); Mei-Hui Lee, Hsinchu Hsien (TW)

(73) Assignee: TAIMIDE TECHNOLOGY INCORPORATION, Hsinchu County (TW)

(21) Appl. No.: 14/292,254

(22) Filed: May 30, 2014

(30) Foreign Application Priority Data
Aug. 27, 2013 (TW) 102130703

(51) Int. Cl. C08L 79/08; H05K 1/05; H05K 1/03

(52) U.S. Cl. CPC C08L 79/08; H05K 1/0373; H05K 1/0393; H05K 1/053; C08L 2205/025
USPC 428/458; 524/538

(57) ABSTRACT

A colored polyimide film includes a polyimide polymer obtained by reacting diamine monomers with dianhydride monomers, wherein the diamine monomers are oxydianiline (ODA) and phenylene diamine (PDA) monomers, and the dianhydride monomers are pyromellitic dianhydride (PMDA); a matting agent comprised of polyimide particles; and one or more color pigment. The polyimide films described herein have low gloss, low transparency, and low coefficient of thermal expansion.

### CROSS-REFERENCE TO RELATED APPLICATION(S)

This application claims priority to Taiwan application no. 102130703 filed on Aug. 27, 2013, the entire contents of which are incorporated herein by this reference.

### BACKGROUND

1. Field of the Invention

The present disclosure relates to colored polyimide films and metal laminate structures containing polyimide films.

2. Description of the Related Art

Flexible circuit boards (FCB) are widely used as component parts in computers, communication products, consumer electronics, optical lens modules, LCD modules and solar cells. A flexible circuit board usually includes a polyimide film as substrate or coverlay owing to its advantageous mechanical strength, flexibility, solvent resistance, dielectric property and heat resistance. Generally, a polyimide film is transparent with a yellowish color, so that circuit patterns on the FCB can be visible even when covered by the polyimide film. For applications in which it is desired to conceal the electric circuit of the FCB and require specific color appearance, the polyimide film needs to have the requisite color and shielding ability.

In addition to the aforementioned requirements, the polyimide film must also have low gloss to offer a fine texture and appealing appearance, and low transmittance of light to protect the electric circuit of the FCB. In general, desirable gloss and light transmittance can be achieved by adding a color pigment and a matting agent. However, the film characteristics (such as coefficient of thermal expansion) may be adversely affected when the color pigment and matting agent are incorporated in inadequate or excessively large amounts, which may lead to a mismatch between the mechanical properties of the polyimide film and those of other adjacent elements in the FCB.

### SUMMARY

Therefore, there is a need for a polyimide film that can exhibit desirable color appearance, provide effective shielding ability and good film properties.

The present application describes a colored polyimide film including a polyimide polymer obtained by reacting diamine monomers with dianhydride monomers, the diamine monomers being oxydianiline (ODA) and phenylene diamine (PDA) monomers, and the dianhydride monomers being pyromellitic dianhydride (PMDA); a matting agent comprised of polyimide particles; and one or more color pigment.

In another embodiment, a red polyimide film is described. The red polyimide film includes a polyimide polymer obtained by reacting diamine monomers with dianhydride monomers, the diamine monomers consisting of oxydianiline (ODA) and phenylene diamine (PDA), and the dianhydride monomers consisting of pyromellitic dianhydride (PMDA); about 6 to about 15 wt % of a polyimide matting agent; about 6 to about 15 wt % of a red pigment; and about 10 to about 22 wt % of a white pigment.

In yet another embodiment, a black polyimide film is described. The black polyimide film includes a polyimide polymer obtained by reacting diamine monomers with dianhydride monomers, the diamine monomers consisting of oxydianiline (ODA) and phenylene diamine (PDA), and the dianhydride monomers consisting of pyromellitic dianhydride (PMDA); about 6 to about 15 wt % of a matting agent comprised of polyimide particles; and about 3 to about 8 wt % of a black pigment.

The present application also describes a metal laminate structure including any of the aforementioned colored polyimide film, and a metal layer contacting with a surface of the polyimide film.

### DETAILED DESCRIPTION OF THE EMBODIMENTS

The present application describes a colored polyimide film that contains a polyimide polymer, a matting agent comprised of polyimide particles, and one or more color pigment. The color pigment is selected according to a desired color for the film. For example, the colored polyimide film may exhibit red color, preferably opaque and cloudy red, or black color.

The colored polyimide film contains at least one of the following film characteristics: low 60° gloss, low coefficient of thermal expansion (CTE) and low light transmission rate (TT). More specifically, the film can have a 60° gloss equal to 15 or lower, preferably 12 or lower, for example 10, 8, 6, 5, 3, 1.

In some embodiments, the colored polyimide film can be associated with a copper foil to form a flexible print circuit (FPC). The mechanical properties of the polyimide film preferably match with those of the copper foil. For example, the CTE of the copper foil is about 17 ppm/° C., and the CTE of the polyimide film preferably matches the CTE of the copper foil to avoid adverse defects such as warpage, deformation or crack. In one embodiment, the CTE of the colored polyimide film can be between about 10 and 28 ppm/° C. The CTE of the polyimide film may vary depending on the composition and the ratios of the pigment and the matting agent incorporated in the film. For example, the ranges of the CTE for a black polyimide film can be between about 10 and 25 ppm/° C., between about 15 and 23 ppm/° C., or between about 17 and 22 ppm/° C.; the various ranges of the CTE for a red polyimide film can be between about 12 and 28 ppm/° C., between about 15 and 28 ppm/° C., or between about 20 and 28 ppm/° C.

In addition to desired color, the colored polyimide film also exhibits improved shielding ability (i.e., low light transmission rate) so that it can effectively protect and shield the electric circuit on a circuit board. More specifically, the colored polyimide film can have a light transmission rate equal to 6% or lower, preferably 5% and lower, such as 4%, 3%, 2%, 1%.

The colored polyimide film can be formed as a single-layer base film comprised of a polyimide polymer. More specifically, the polyimide polymer of the base film can be obtained by reacting diamine monomers with dianhydride monomers in a substantially equal molar ratio. The diamine monomers are oxydianiline (ODA) and phenylene diamine (PDA), and the dianhydride monomers are pyromellitic dianhydride (PMDA). Examples of ODA include 3,4-ODA, 4,4′-ODA and the like. Examples of PDA include p-PDA, m-PDA and the like.

The diamine molar ratio of ODA:PDA is about 0.9:0.1 to about 0.5:0.5. Based on the total mole of the diamine monomers, the ratio of ODA thus can exemplary be 90%, 88%, 85%, 80%, 75%, 70%, 63%, 60%, 55%, 50%, or any intermediate values between 90% and 50%. Based on the total mole of the diamine monomers, the corresponding ratio of PDA can exemplary be 10%, 15%, 20%, 25%, 30%, 35%, 38%, 40%, 45%, 50%, or any intermediate values between 10% and 50%.

In a preferred embodiment, based on the total mole of the diamine monomers, the amount of ODA is between about 55 and about 85%, and the amount of PDA is between about 15 and about 45%. More specifically, the amount of ODA can be between about 60 and about 70%, and the amount of PDA can be between about 30 and about 40%.

The matting agent used in the colored polyimide film is a polyimide powder. The polyimide matting agent can be derived from diamine and dianhydride monomers. Examples of the diamine monomers can include p-PDA, ODA, PBOA and the like. Examples of the dianhydride monomer can include BPDA, PMDA and the like. Moreover, one or more type of diamine monomers can be reacted with one or more time of dianhydride monomers to obtain the polyimide matting agent. For example, the polyimide powder can be obtained by reacting ODA with PMDA, ODA with BPDA, PDA with BPDA, PBOA with PMDA, or PDA and ODA with PMDA. In some embodiment, the same monomer combination used for forming the polyimide polymer of the base film may also be applied to manufacture the polyimide powder. The average particle size in the polyimide powder is between about 3 and about 8 μm.

In one embodiment, the weight ratio of the polyimide matting agent is between about 4 and about 15 wt % based on the total weight of the base film, for example between 6 and 15 wt %, and preferably between 6 and 12 wt %.

The color pigment used in the colored polyimide film can be selected from red pigments, white pigments and black pigments, which can be used alone or in combination. The color pigment can include organic or inorganic pigments. In some embodiments, the organic or inorganic pigment can also be selected from compounds classified in a color index (C.I.) (e.g., the color index published by The Society of Dyers and Colourists).

In some embodiments, a red pigment can be used to manufacture a polyimide base film having red color. The red pigment can include, without limitation, Cadmium Red, Cadmium Vermilion, Alizarin Crimson, Permanent Magenta, Scarlet Lake and the like. Other examples of suitable red pigments can include C.I. pigment red 9, C.I. pigment red 97, C.I. pigment red 105, C.I. pigment red 122, C.I. pigment red 123, C.I. pigment red 144, C.I. pigment red 149, C.I. pigment red 166, C.I. pigment red 168, C.I. pigment red 176, C.I. pigment red 177, C.I. pigment red 180, C.I. pigment red 192, C.I. pigment red 209, C.I. pigment red 215, C.I. pigment red 216, C.I. pigment red 224, C.I. pigment red 242, C.I. pigment red 254, C.I. pigment red 264, C.I. pigment red 265 and the like.

White pigments used for fabricating the colored polyimide film can include, without limitation, titanium dioxide (TiO₂) (e.g., rutile TiO₂, anatase TiO₂ or brookite TiO₂), zirconium oxide (ZrO₂), calcium oxide (CaO), zinc oxide (ZnO₂), aluminum oxide (Al₂O₃), zinc sulfide (ZnS₂), calcium carbonate (CaCO₃), lead carbonate (PbCO₃), lead hydroxide (Pb(OH)₂), calcium sulfate (CaSO₄), barium sulfate (BaSO₄), silicon dioxide (SiO₂), boron nitride (BN), aluminum nitride (AlN), basic zinc molybdate, basic calcium zinc molybdate, lead white, molybdenum white, lithopone (a mixture of barium sulfate and zinc sulfide), clay and the like.

Black pigments used for fabricating the colored polyimide film can include, without limitation, carbon black, cobalt oxide, Fe—Mn—Bi black, Fe—Mn oxide spinel black, (Fe,Mn)₂O₃ black, copper chromite black spinel, lampblack, bone black, bone ash, bone char, hematite, iron oxide black, micaceous iron oxide, black complex inorganic color pigment (CICP), CuCr₂O₄ black, (Ni,Mn,Co)(Cr,Fe)₂O₄ black, aniline black, perylene black, anthraquinone black, chrome green black hematite, iron-chromium mixed oxides and the like. Other examples of suitable black pigments can include C.I. pigment black 1, C.I. pigment black 7 and the like.

According to one embodiment, a red polyimide film may be fabricated by incorporating a red pigment at a weight ratio between about 6 and about 15 wt % of the total weight of the film. In addition to the red pigment, a white pigment may be optionally incorporated in the film composition to produce the desired shielding effect. According to another embodiment, a red polyimide film may be fabricated by incorporating a red pigment and a white pigment, the weight ratio of the red pigment being between about 6 and about 15 wt %, and the weight ratio of the white pigment being between about 10 and about 22 wt %. In yet another variant embodiment, a red polyimide film may also be fabricated by incorporating a red pigment and a black pigment, the weight ratio of the red pigment being between about 6 and about 15 wt %, and the weight ratio of the black pigment being between about 3 and about 8 wt %.

In some embodiments, a black polyimide film is prepared by using a black pigment. For example, the black pigment occupies 3-8 wt % of the total weight of the film.

The colored polyimide film can be used in a metal laminate structure, which includes a metal layer arranged in contact with a surface of the polyimide film. The metal layer can be formed by physical vapor deposition, chemical vapor deposition, evaporation deposition, electrolytic plating, or electroless plating. In one embodiment, the metal layer can contain gold, silver, copper, aluminum, nickel, any alloy thereof, which can be used alone or in combination.

### EXAMPLES

### Preparation of a Polyimide Matting Agent

About 400 g of a polyamic acid (PAA) solution with 6% of solid content copolymerized by 4,4′-ODA, p-PDA and PMDA is introduced in a three-necked flask. The PAA solution is agitated and heated with 2° C./min of heating rate to 160° C. The reaction is then conducted at 160° C. for 3 hours to produce a precipitate of polyimide. After cooling down to room temperature, the precipitate of polyimide is washed by DMAC and ethanol, filtrated in vacuum, and baked at about 160° C. in an oven for 1 hour. Polyimide powder (PIP) then can be obtained.

About 10 g of the dried polyimide powder is mixed with 60 g of DMAC, agitated under room temperature for 1 hour, and further ground by grinder to obtain a slurry of the matting agent containing polyimide particles. The diameter of the polyimide particles is between about 3 and about 8 nm, which can be measured by using a scanning electronic microscope (Catalog No. JEOL5410).

Preparation of a Pigment Slurry:

For a red slurry, pigment red 149 (sold by Everlight Chemical under the trade name Red04) containing 10% of solid content is processed through a grinder prior to use as the red slurry.

For a white slurry, the white pigment (sold by Everlight Chemical under the trade name: White01 and containing TiO₂) containing 50% of solid content is processed through a grinder prior to use as the white slurry.

For a black slurry, about 100 g of carbon black (sold by EVONIK Company as Catalog No. SB4A) and 600 g of DMAC are mixed and agitated for 1 hour. The mixture is then processed through a grinder to obtain a carbon black slurry.

The aforementioned pigment slurries can be used for fabricating colored polyimide films as described hereinafter.

### Example 1

About 400 g of DMAC is introduced in a reaction flask, and about 35.86 g of 4,4′-ODA (i.e., corresponding to about 0.1793 mole) and about 8.3 g of p-PDA (i.e., corresponding to about 0.0768 mole) are incorporated in the DMAC solvent and agitated until complete dissolution. About 55.84 g of PMDA (i.e., corresponding to about 0.2561 mole) is then added and continuously agitated for 4 hours to obtain a PAA solution having a viscosity of about 200,000 cps.

About 30 g of the obtained PAA solution is placed in a 100 mL reaction flask and diluted with about 26.81 g of DMAc. About 7.88 g of the red slurry, about 2.37 g of the white slurry, and about 3.31 g of the slurry containing the polyimide particles are then added into the flask, continuously agitated for 1 hour, and refrigerated for 30 minutes.

The above PAA solution is then mixed with a dehydrant acetic anhydride and a catalyst picoline at a molar ratio PAA:acetic anhydride:picoline equal to about 1:2:1. Then, a layer of the solution is coated on a glass plate support by using a coating blade, baked at 80° C. for 30 minutes and then at 170-370° C. for 4 hours. A colored polyimide film can be thereby formed and peeled from the plate support.

### Example 2

A polyimide film can be prepared like in Example 1, except that the ingredients include about 38 g of the PAA solution, about 26.47 g of DMAc, about 2.71 g of the carbon black slurry, and about 3.33 g of the slurry containing the polyimide particles.

### Comparative Example 1

About 400 g of DMAC is introduced in a reaction flask, and about 47.85 g of 4,4′-ODA (i.e., corresponding to about 0.2393 mole) is incorporated in the DMAC solvent and agitated until complete dissolution. About 51.11 g of PMDA (i.e., corresponding to about 0.2344 mole) is then added and continuously agitated for 4 hours to obtain a PAA solution having a viscosity of about 200,000 cps.

About 30 g of the obtained PAA solution is then mixed with about 26.47 g of DMAC, about 7.95 g of the red slurry, about 2.38 g of the white slurry, and about 3.33 g of the slurry containing the polyimide particles. Subsequently, the same next processing steps as described in Example 1 (e.g., addition of dehydrant and catalyst, coating and baking) can be applied to form a polyimide film.

### Comparative Example 2

A polyimide film can be prepared like in Comparative Example 1, except that the ingredients include about 38 g of the PAA solution of Comparative Example 1, about 26.48 g of DMAc, about 2.73 g of the carbon black slurry, and about 3.27 g of the slurry containing the polyimide particles.

### Comparative Example 3

About 400 g of DMAC is put in a reaction flask, and about 39.22 g of 4,4′-ODA (i.e., corresponding to about 0.1961 mole) is incorporated in the DMAC solvent and agitated until complete dissolution. About 59.57 g of 4,4-Oxydiphthalic anhydride (ODPA) (i.e., corresponding to about 0.1922 mole) is then added and continuously agitated for 4 hours to obtain a PAA solution having a viscosity of about 200,000 cps.

About 30 g of the obtained PAA solution is then mixed with about 26.48 g of DMAC, about 8.08 g of the red slurry, about 2.73 g of the white slurry, and about 3.27 g of the slurry containing the polyimide particles. Subsequently, the same next processing steps as described in Example 1 can be applied to form a polyimide film.

### Comparative Example 4

About 400 g of DMAC is put in a reaction flask, and about 14.04 g of p-PDA (i.e., corresponding to about 0.13 mole) and about 29.28 g of PBOA (i.e., corresponding to about 0.13 mole) are then incorporated and agitated to complete dissolution. About 55.55 g of PMDA (i.e., corresponding to about 0.2548 mole) is then added and continuously agitated for 4 hours to obtain a PAA solution having a viscosity of about 200,000 cps.

About 30 g of the obtained PAA solution is mixed with about 26.81 g of DMAC, about 7.88 g of the red slurry, about 2.36 g of the white slurry, and about 3.31 g of the slurry containing the polyimide particles. Subsequently, the same next processing steps as described in Example 1 can be applied to form a polyimide film.

### Comparative Example 5

About 400 g of DMAC is put in a reaction flask, and about 33.13 g of p-PDA (i.e., corresponding to about 0.3068 mole) is then incorporated and agitated to complete dissolution. About 65.54 g of PMDA (i.e., corresponding to about 0.3006 mole) is then added and continuously agitated for 4 hours to obtain a PAA solution having a viscosity of about 200,000 cps.

About 30 g of the obtained PAA solution is mixed with about 26.68 g of DMAC, about 7.74 g of the red slurry, about 2.32 g of the white slurry, and about 3.25 g of the slurry containing the polyimide particles. Subsequently, the same next processing steps as described in Example 1 can be conducted to form a polyimide film.

### Comparative Example 6

A polyimide film can be prepared like in Comparative Example 5, except that the ingredients include about 38 g of the PAA solution of Comparative Example 5, about 26.45 g of DMAc, about 2.66 g of the carbon black slurry, and about 3.19 g of the slurry containing the polyimide particles.

The polyimide films fabricated according to the aforementioned Examples and Comparative Examples can be tested to measure certain film characteristics including 60° gloss, total transparency and CTE. The measures are conducted with the following equipment, and the results of the measures are shown in Table 1 below.

60° Gloss

The glossmeter sold under the designation Micro Tri Gloss—BYK Gardner is used to measure the 60° gloss value, which can be obtained as an average of three distinct measures.

Total Transparency (TT)

The haze meter sold under the designation NIPPON DEMSHOKU NDH 2000 is used to measure the total transparency, which can be obtained as an average of three to six distinct measures.

Linear Coefficient of Thermal Expansion (CTE)

The thermal mechanical analyzer TMAQ400 (sold by TA Instruments, Inc.) is used to measure the CTE, which can be obtained as an average of the CTE between 100-200° C.

TABLE 1

| | | | Pigment | | | PIP | | Film | | | |
|---|---|---|---|---|---|---|---|---|---|---|---|
| | | | ratio (%) | | | ratio | Film-forming | thickness | 60° gloss | TT | CTE |
| | Monomers | Molar ratio | red | white | black | (%) | ability | (μm) | (GU) | (%) | (ppm/° C.) |
| Example 1 | ODA/PDA/PMDA | 0.7/0.3/1 | 10 | 15 | — | 6 | good | 12.6 | 32.7 | 5.07 | 22.4 |
| Example 2 | ODA/PDA/PMDA | 0.7/0.3/1 | — | — | 5 | 6 | good | 12.4 | 34.2 | 0.24 | 19.6 |
| Comparative | ODA/PMDA | 1/1 | 10 | 15 | — | 6 | good | 13.1 | 32.5 | 5.04 | 31.6 |
| Example 1 | | | | | | | | | | | |
| Comparative | ODA/PMDA | 1/1 | — | — | 5 | 6 | good | 13.2 | 35.5 | 0.20 | 31.2 |
| Example 2 | | | | | | | | | | | |
| Comparative | ODA/ODPA | 1/1 | 10 | 15 | — | 6 | good | 13.1 | 33.2 | 5.02 | 46.6 |
| Example 3 | | | | | | | | | | | |
| Comparative | BPOA/PDA/PMDA | 1/1/1 | 10 | 15 | — | 6 | poor | 12.6 | 33.8 | 4.99 | 8.5 |
| Example 4 | | | | | | | | | | | |

| | | | | | | | |
|---|---|---|---|---|---|---|---|
| Comparative | PDA/PMDA | 1/1 | 10 | 15 | — | 6 | No film formed |
| Example 5 | | | | | | | |
| Comparative | PDA/PMDA | 1/1 | — | — | 5 | 6 | No film formed |
| Example 6 | | | | | | | |

As shown in Table 1, the polyimide films fabricated according to Examples 1 and 2 (i.e., derived from ODA, PDA and PMDA and including suitable amounts of the color pigment and the polyimide matting agent (PIP)) can be effectively formed with a gloss value lower than 35 and a high shielding ability (total transparency (TT) lower than 6%). Moreover, the polyimide films fabricated according to Examples 1 and 2 have a CTE that is between 20 and 22 ppm/° C., which is close to the typical CTE of a copper foil (about 17 ppm/° C.). Accordingly, these films can be particularly suitable as cover films for circuit boards incorporating copper elements.

In contrast, the polyimide films fabricated according to Comparative Examples 1-6 do not exhibit advantageous characteristics. In particular, the films fabricated according to Comparative Examples 1-3 have a CTE that is higher than 30 ppm/° C., which cannot match with the CTE of a copper foil. The use of such films may cause warpage, deformation, or crack. On the other hand, the measures obtained for Comparative Example 4 reveals a poor film-forming ability, and the CTE of any formed film is extremely low (only 8.5 ppm/° C.) and cannot match the CTE of a copper foil. In the case of Comparative Examples 5 and 6, no film can be formed at all.

The results and measures shown in Table 1 reveal that advantageous characteristics can be obtained only when the polyimide film is derived from certain combination of diamine and dianhydride monomers. More specifically, the specific combination of ODA and PDA as diamine monomers with PMDA as dianhydride monomers, combined with a color pigment and a polyimide matting agent, can effectively produce a colored polyimide film with excellent optical characteristics, and CTE-matching with a copper foil.

In order to investigate the impact on the film characteristics, further experiments are conducted in Examples 3 through 8 and Comparative Examples 7 through 15 described hereinafter, all of which using ODA and PDA diamine monomers and PMDA dianhydride monomers to produce a polyimide film.

### Example 3

About 400 g of DMAC is introduced in a reaction flask, and about 44.03 g of 4,4′-ODA (i.e., corresponding to about 0.2202 mole) and about 2.64 g of p-PDA (i.e., corresponding to about 0.0244 mole) are incorporated in the DMAC solvent and agitated until complete dissolution. About 52.26 g of PMDA (i.e., corresponding to about 0.2397 mole) is then added and continuously agitated for 4 hours to obtain a PAA solution having a viscosity of about 200,000 cps.

About 25 g of the obtained PAA solution is mixed with about 22.62 g of DMAC, about 4.8 g of the red slurry, about 3.52 g of the white slurry, and about 8.39 g of the slurry of the polyimide matting agent. Subsequently, the same next processing steps as described in Example 1 can be applied to form a polyimide film.

### Example 4

A polyimide film can be prepared like in Example 1, except that the ingredients include about 25 g of the PAA solution of Example 1, about 28.55 g of DMAc, about 4.77 g of the red slurry, about 3.5 g of the white slurry, and about 8.34 g of the slurry of the polyimide matting agent.

### Example 5

About 400 g of DMAC is put in a reaction flask, and about 26.88 g of 4,4′-ODA (0.1344 mole) and about 14.52 g of p-PDA (0.1344 mole) are then incorporated and agitated until complete dissolution. About 57.43 g of PMDA (0.2634 mole) is then added and continuously agitated for 4 hours to obtain a PAA solution having a viscosity of about 200,000 cps.

About 25 g of the obtained PAA solution is mixed with about 28.51 g of DMAC, about 4.75 g of the red slurry, about 3.49 g of the white slurry, and about 8.31 g of the slurry of the polyimide matting agent. Subsequently, the same next processing steps as described in Example 1 can be conducted to form a polyimide film.

### Example 6

A polyimide film can be prepared like in Example 1, except that the ingredients include about 26 g of the PAA solution of Example 1, about 21.93 g of DMAc, about 11.79 g of the red slurry, about 1.57 g of the white slurry, and about 8.24 g of the slurry of the polyimide matting agent.

### Example 7

A polyimide film can be prepared like in Example 1, except that the ingredients include about 35 g of the PAA solution of Example 1, about 25.2 g of DMAc, about 1.62 g of the carbon black slurry, and about 8.12 g of the slurry of the polyimide matting agent.

### Example 8

A polyimide film can be prepared like in Example 1, except that the ingredients include about 33 g of the PAA solution of Example 1, about 24.4 g of DMAc, about 4.35 g of the carbon black slurry, and about 8.15 g of the slurry of the polyimide matting agent.

### Comparative Example 7

About 400 g of DMAC is introduced in a reaction flask, and about 45.96 g of 4,4′-ODA (i.e., corresponding to about 0.2298 mole) and about 1.31 g of p-PDA (i.e., corresponding to about 0.0121 mole) are incorporated in the DMAC solvent and agitated until complete dissolution. About 51.68 g of PMDA (i.e., corresponding to about 0.2371 mole) is then added and continuously agitated for 4 hours to obtain a PAA solution having a viscosity of about 200,000 cps.

About 25 g of the obtained PAA solution is then mixed with about 28.63 g of DMAC, about 4.8 g of the red slurry, about 3.52 g of the white slurry and about 8.4 g of the slurry of the polyimide matting agent. Subsequently, the same next processing steps as described in Example 1 can be applied to form a polyimide film.

### Comparative Example 8

About 400 g of DMAC is introduced in a reaction flask, and about 22.05 g of 4,4′-ODA (i.e., corresponding to about 0.1103 mole) and about 17.86 g of p-PDA (i.e., corresponding to about 0.1654 mole) are incorporated into the DMAC solvent and agitated until complete dissolution. About 58.89 g of PMDA (i.e., corresponding to about 0.2701 mole) is then added and continuously agitated for 4 hours to obtain a PAA solution having a viscosity of about 200,000 cps.

About 25 g of the obtained PAA solution is then mixed with about 22.62 g of DMAC, about 4.74 g of the red slurry, about 3.48 g of the white slurry, and about 8.29 g of the slurry of the polyimide matting agent. Subsequently, the same next processing steps as described in Example 1 can be applied to form a polyimide film.

### Comparative Example 9

A polyimide film can be prepared like in Example 1, except that the ingredients include about 16 g of the PAA solution of Example 1, about 25.32 g of DMAc, about 16.58 g of the red slurry, about 4.97 g of the white slurry, and about 8.7 g of the slurry of the polyimide matting agent.

### Comparative Example 10

A polyimide film can be prepared like in Example 1, except that the ingredients include about 33 g of the PAA solution of Example 1, about 25.63 g of DMAc, about 2.33 g of the red slurry, about 0.78 g of the white slurry, and about 8.15 g of the slurry of the polyimide matting agent.

### Comparative Example 11

A polyimide film can be prepared like in Example 1, except that the ingredients include about 32 g of the PAA solution of Example 1, about 23.93 g of DMAc, about 5.41 g of the carbon black slurry, and about 8.12 g of the slurry of the polyimide matting agent.

### Comparative Example 12

A polyimide film can be prepared like in Example 1, except that the ingredients include about 36 g of the PAA solution of Example 1, about 25.61 g of DMAc, about 0.27 g of the carbon black slurry, and about 8.1 g of the slurry of the polyimide matting agent.

### Comparative Example 13

A polyimide film can be prepared like in Example 1, except that the ingredients include about 40 g of the PAA solution of Example 1, about 26.97 g of DMAc, and about 1.57 g of the slurry of the polyimide matting agent.

### Comparative Example 14

A polyimide film can be prepared like in Example 1, except that the ingredients include about 30 g of the PAA solution of Example 1, about 23.13 g of DMAc, and about 16.3 g of the slurry of the polyimide matting agent.

### Comparative Example 15

A polyimide film can be prepared like in Example 1, except that the ingredients include about 33 g of the PAA solution of Example 1, about 22.27 g of DMAc, about 7.98 g of the red slurry, and about 8.37 g of the slurry of the polyimide matting agent.

Table 2 shows the measures of 60° gloss value, total transparency (TT) and CTE obtained for the polyimide films prepared according to the above Examples 3 through 8 and Comparative Examples 7 through 15.

TABLE 2

| | | | | | PIP | | Film | 60° | | |
|---|---|---|---|---|---|---|---|---|---|---|
| | Molar ratio | Pigment ratio (%) | | | ratio | Film-forming | thickness | gloss | TT | CTE |
| | ODA/PDA/PMDA | red | white | black | (%) | ability | (μm) | (GU) | (%) | (ppm/° C.) |
| Example 3 | 0.9/0.1/1 | 6 | 22 | — | 15 | good | 13.1 | 8.1 | 3.51 | 27.9 |
| Example 4 | 0.7/0.3/1 | 6 | 22 | — | 15 | good | 13.2 | 8.6 | 3.53 | 22.4 |
| Example 5 | 0.5/0.5/1 | 6 | 22 | — | 15 | good | 12.4 | 8.3 | 3.50 | 24.4 |
| Example 6 | 0.7/0.3/1 | 15 | 10 | — | 15 | good | 12.5 | 8.4 | 5.41 | 22.7 |
| Example 7 | 0.7/0.3/1 | — | — | 3 | 15 | good | 13.3 | 10.1 | 1.13 | 19.1 |
| Example 8 | 0.7/0.3/1 | — | — | 8 | 15 | good | 12.7 | 10.2 | 0.04 | 21.5 |
| Comparative | 0.95/0.05/1 | 6 | 22 | — | 15 | good | 13.2 | 8.8 | 3.52 | 31.0 |
| Example 7 | | | | | | | | | | |
| Comparative | 0.4/0.6/1 | 6 | 22 | — | 15 | poor | 12.7 | 8.7 | 3.53 | 21.8 |
| Example 8 | | | | | | | | | | |
| Comparative | 0.7/0.3/1 | 20 | 30 | — | 15 | poor | 12.5 | 7.0 | 2.43 | 23.8 |
| Example 9 | | | | | | | | | | |
| Comparative | 0.7/0.3/1 | 3 | 5 | — | 15 | good | 13.1 | 8.9 | 13.03 | 22.1 |
| Example 10 | | | | | | | | | | |
| Comparative | 0.7/0.3/1 | — | — | 10 | 15 | poor | 13.3 | 11.2 | 0.01 | 21.8 |
| Example 11 | | | | | | | | | | |
| Comparative | 0.7/0.3/1 | — | — | 0.5 | 15 | good | 13.2 | 11.9 | 49.95 | 18.8 |
| Example 12 | | | | | | | | | | |
| Comparative | 0.7/0.3/1 | — | — | — | 3 | good | 13.1 | 85.4 | 71.40 | 18.4 |
| Example 13 | | | | | | | | | | |
| Comparative | 0.7/0.3/1 | — | — | — | 30 | poor | 12.8 | 3.2 | 62.56 | 23.5 |
| Example 14 | | | | | | | | | | |
| Comparative | 0.7/0.3/1 | 10 | — | — | 15 | good | 12.7 | 10.4 | 34.8 | 21.3 |
| Example 15 | | | | | | | | | | |

A study of the measures obtained for Examples 3 through 5 and Comparative Examples 7 through 8 reveals that the advantageous gloss, shielding ability and CTE can be obtained for a specific molar ratio of monomers. More specifically, the diamine molar ratio of ODA:PDA is preferably 0.9-0.5:0.1-0.5. In contrast, the combination of a relatively higher amount of ODA with a relatively lower amount of PDA, such as shown by the measures of Comparative Example 7, can result in a film that has undesirably high CTE (more than 30 ppm/° C.), which may lead to CTE mismatch between the polyimide film and the copper foil. On the other hand, the measures of Comparative Example 8 show that the combination of a relatively lower amount of ODA with a relatively higher amount of PDA may result in a poor film-forming ability, which is unsuitable for large scale manufacture.

The measures of Comparative Examples 9, 11, and 14 also reveal that an excessive amount of color pigment or polyimide matting agent may also result in a poor film-forming ability, and adversely affect the mechanical properties of the polyimide film. On the other hand, the measures of Comparative Examples 10, 12 and 15 show that lower amounts of the color pigment or non-addition of the white slurry do not affect the film-forming ability, but the obtained polyimide film has extremely high light transmittance, which makes it unsuitable as a coverlay for shielding a circuit pattern on a circuit board. In other words, the polyimide films fabricated according to Comparative Examples 10, 12 and 15 are not suitable for circuit board applications owing to its insufficient optical properties. The measures of Comparative Example 13 show that a significantly low amount of the matting agent (i.e., less than 6 wt %) can result in a polyimide that has undesirably high 60° gloss.

As described herein, a combination of ODA and PDA diamine monomers with PMDA dianhydride monomers can be applied with a suitable amount of color pigment and polyimide matting agent to effectively fabricate a colored polyimide film having desirable low gloss (i.e., 60° gloss value equal to or lower than 15), high shielding ability (i.e., total transparency TT less than 6%), and a CTE (i.e., 28 ppm/° C. or less) that can match with the CTE of a copper foil.

The foregoing realizations have been described in the context of particular embodiments. These embodiments are meant to be illustrative and not limiting. Many variations, modifications, additions, and improvements are possible. Accordingly, plural instances may be provided for components described herein as a single instance. Structures and functionality presented as discrete components in the exemplary configurations may be implemented as a combined structure or component. These and other variations, modifications, additions, and improvements may fall within the scope as defined in the claims that follow.

What is claimed is:

1. A base film comprising:
a polyimide polymer obtained by reacting diamine monomers with dianhydride monomers, the diamine monomers being oxydianiline (ODA) and phenylene diamine (PDA) monomers, and the dianhydride monomers being pyromellitic dianhydride (PMDA);
a matting agent comprised of polyimide particles; and
one or more color pigments.

2. The base film according to claim 1, wherein a diamine molar ratio of ODA:PDA is about 0.9:0.1 to about 0.5:0.5.

3. The base film according to claim 1, wherein the matting agent is present in an amount between about 4 and about 15 wt % based on the total weight of the base film.

4. The base film according to claim 1, wherein the color pigment is selected from a group consisting of a red pigment, a white pigment and a black pigment.

5. The base film according to claim 1, wherein the color pigment contains a red pigment and a white pigment, and the red pigment is present in an amount between about 6 and about 15 wt % based on the total weight of the film.

6. The base film according to claim 5, wherein the white pigment is present in an amount between about 10 and about 22 wt % based on the total weight of the film.

7. The base film according to claim 1, wherein the color pigment contains a black pigment that is present in an amount between about 3 and about 8 wt % based on the total weight of the film.

8. The base film according to claim 1, having a 60° gloss equal to or lower than 15, a coefficient of thermal expansion (CTE) equal to or lower than 28 ppm/° C., and a light transmission rate equal to or lower than 6%.

9. A metal laminate structure comprising:
a base film according to claim 1; and
a metal layer contacting with a surface of the base film.

10. The metal laminate structure according to claim 9, wherein the metal layer is formed by physical vapor deposition, chemical vapor deposition, evaporation deposition, electrolytic plating, or electroless plating.

11. The metal laminate structure according to claim 9, wherein the metal layer includes a metal selected from a group consisting of gold, silver, copper, aluminum, nickel, and an alloy thereof.

12. A base film having red color, comprising:
a polyimide polymer obtained by reacting diamine monomers with dianhydride monomers, the diamine monomers consisting of oxydianiline (ODA) and phenylene diamine (PDA), and the dianhydride monomers consisting of pyromellitic dianhydride (PMDA);
about 6 to about 15 wt % of a polyimide matting agent;
about 6 to about 15 wt % of a red pigment; and
about 10 to about 22 wt % of a white pigment.

13. The base film according to claim 12, wherein a diamine molar ratio of ODA:PDA is about 0.9:0.1 to about 0.5:0.5.

14. A base film having black color, comprising:
a polyimide polymer obtained by reacting diamine monomers with dianhydride monomers, the diamine monomers consisting of oxydianiline (ODA) and phenylene diamine (PDA), and the dianhydride monomers consisting of pyromellitic dianhydride (PMDA);
about 6 to about 15 wt % of a matting agent comprised of polyimide particles; and
about 3 to about 8 wt % of a black pigment.

15. The base film according to claim 14, wherein a diamine molar ratio of ODA:PDA is about 0.9:0.1 to about 0.5:0.5.
